(19) United States
(12) Patent Application Publication
(10) Pub. No.: US 2024/0065055 A1
(43) Pub. Date: Feb. 22, 2024

(54) DISPLAY APPARATUS

(71) Applicant: Samsung Display Co., Ltd., Yongin-si (KR)

(72) Inventors: Heehwan Lee, Yongin-si (KR); Yoonmi Lee, Yongin-si (KR)

(21) Appl. No.: 18/310,413

(22) Filed: May 1, 2023

(30) Foreign Application Priority Data
Aug. 22, 2022 (KR) 10-2022-0105072

(51) Int. Cl. H10K 59/131

(52) U.S. Cl. CPC H10K 59/131

(57) ABSTRACT

A display apparatus includes: a substrate comprising a first area and a second area adjacent to each other; a plurality of wirings on the substrate and extending in a first direction from the first area toward the second area; and a lower layer between the substrate and the plurality of wirings and comprising an inclined surface portion, wherein the plurality of wirings comprise two adjacent wirings, and in a plan view, a first portion in which one of the two adjacent wirings overlaps the inclined surface portion is in a diagonal direction crossing the first direction with respect to a second portion in which the other of the two adjacent wirings overlaps the inclined surface portion.

### CROSS-REFERENCE TO RELATED APPLICATION

The present application claims priority to and the benefit of Korean Patent Application No. 10-2022-0105072, filed on Aug. 22, 2022, in the Korean Intellectual Property Office, the entire disclosure of which is incorporated herein by reference in its entirety.

### BACKGROUND

### 1. Field

Aspects of one or more embodiments relate to a display apparatus.

### 2. Description of the Related Art

Recently, the various uses and potential applications of display apparatuses has diversified. In addition, as display apparatuses have become relatively thinner and lighter, their range of uses has gradually expanded.

Among display apparatuses, organic light-emitting display apparatuses have relatively wide viewing angles, relatively excellent contrast, and relatively fast response speeds, and thus have drawn attention as next-generation display apparatuses.

In general, an organic light-emitting display apparatus includes a thin-film transistor and an organic light-emitting diode, which is a display element, on a substrate, and the organic light-emitting diode emits light by itself. Such an organic light-emitting display apparatus may be used as a display of a small-sized product, such as a mobile phone, or as a display of a large-sized product, such as a television.

The above information disclosed in this Background section is only for enhancement of understanding of the background and therefore the information discussed in this Background section does not necessarily constitute prior art.

### SUMMARY

Aspects of one or more embodiments include a display apparatus in which a short circuit defect between adjacent wirings in a stepped structure may be prevented or reduced. However, such characteristics are only an example, and the scope of embodiments according to the present disclosure are not limited thereto.

Additional aspects will be set forth in part in the description which follows and, in part, will be apparent from the description, or may be learned by practice of the presented embodiments of the disclosure.

According to one or more embodiments, a display apparatus includes a substrate including a first area and a second area adjacent to each other, a plurality of wirings on the substrate and extending in a first direction from the first area toward the second area, and a lower layer arranged between the substrate and the plurality of wirings and including an inclined surface portion, wherein the plurality of wirings include two adjacent wirings, and, in a plan view, a first portion in which one of the two adjacent wirings overlaps the inclined surface portion is arranged in a diagonal direction crossing the first direction with respect to a second portion in which the other of the two adjacent wirings overlaps the inclined surface portion.

According to some embodiments, in a plan view, the inclined surface portion may include an uneven shape in which a protruding portion and a recessed portion are repeatedly arranged.

According to some embodiments, the protruding portion may be a portion that protrudes in a direction toward the second area, and the recessed portion may be a portion that is recessed in a direction toward the first area.

According to some embodiments, one of the two adjacent wirings may overlap the protruding portion of the inclined surface portion, and the other of the two adjacent wirings may overlap the recessed portion of the inclined surface portion.

According to some embodiments, the protruding portion and the recessed portion may each have a quadrangular shape.

According to some embodiments, the protruding portion and the recessed portion may each have a triangular shape, and the two adjacent wirings may pass through vertices of the triangle.

According to some embodiments, in a plan view, the inclined surface portion may include an oblique shape that is inclined with respect to the first direction and a second direction perpendicular to the first direction.

According to some embodiments, the plurality of wirings may be arranged on a same layer and include a same material.

According to some embodiments, the lower layer may include a plurality of sub-layers.

According to some embodiments, the display apparatus may further include a light-emitting diode on the substrate, wherein the light-emitting diode may include a sub-pixel electrode, an emission layer on the sub-pixel electrode, and an opposite electrode on the emission layer.

According to one or more embodiments, a display apparatus includes a substrate including a first area and a second area adjacent to each other, a plurality of wirings on the substrate and extending in a first direction from the first area toward the second area, and a lower layer arranged between the substrate and the plurality of wirings, wherein an upper surface of the lower layer includes a first surface portion arranged in the first area, a second surface portion arranged in the second area and having a vertical distance that is smaller than a vertical distance from the substrate to the first surface portion, and an inclined surface portion between the first surface portion and the second surface portion, wherein the plurality of wirings include two adjacent wirings, and, in a plan view, a first portion in which one of the two adjacent wirings overlaps the inclined surface portion is arranged in a diagonal direction crossing the first direction with respect to a second portion in which the other of the two adjacent wirings overlaps the inclined surface portion.

According to some embodiments, the inclined surface portion may have a vertical distance that is smaller than the vertical distance from the substrate to the first surface portion and greater than a vertical distance from the substrate to the second surface portion.

According to some embodiments, in a plan view, the inclined surface portion may include an uneven shape in which a protruding portion and a recessed portion are repeatedly arranged.

According to some embodiments, the protruding portion may be a portion that protrudes in a direction toward the second area, and the recessed portion may be a portion that is recessed in a direction toward the first area.

According to some embodiments, one of the two adjacent wirings may overlap the protruding portion of the inclined surface portion, and the other of the two adjacent wirings may overlap the recessed portion of the inclined surface portion.

According to some embodiments, the protruding portion and the recessed portion may each have a quadrangular shape.

According to some embodiments, the protruding portion and the recessed portion may each have a triangular shape, and the two adjacent wirings may pass through vertices of the triangle.

According to some embodiments, in a plan view, the inclined surface portion may include an oblique shape that is inclined with respect to the first direction and a second direction perpendicular to the first direction.

According to some embodiments, the plurality of wirings may be arranged on a same layer and include a same material.

According to some embodiments, the lower layer may include a plurality of sub-layers.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a perspective view schematically illustrating a display apparatus according to some embodiments;

FIG. 2 is a plan view schematically illustrating a display panel that may be included in a display apparatus, according to some embodiments;

FIG. 3 is an equivalent circuit diagram schematically illustrating a light-emitting diode of a display panel and a sub-pixel circuit electrically connected thereto, according to some embodiments;

FIG. 4 is a cross-sectional view schematically illustrating a portion of a display panel according to some embodiments;

FIG. 5 is a plan view schematically illustrating a portion of a display panel according to some embodiments;

FIG. 6 is a cross-sectional view schematically illustrating a portion of a display panel according to some embodiments;

FIGS. 7A and 7B are cross-sectional views illustrating a method of manufacturing a portion of a display panel, according to some embodiments;

FIG. 8 is a plan view schematically illustrating a portion of a display panel according to some embodiments, and is an enlarged plan view of a region X of FIG. 5;

FIG. 9 is a plan view schematically illustrating a portion of a display panel according to some embodiments;

FIG. 10 is a plan view schematically illustrating a portion of a display panel according to some embodiments;

FIG. 11 is a plan view schematically illustrating a portion of a display panel according to some embodiments;

FIGS. 12 and 13 are plan views schematically illustrating a portion of a display panel according to some embodiments;

FIG. 14 is a plan view schematically illustrating a portion of a display apparatus according to some embodiments;

FIG. 15 is a cross-sectional view schematically illustrating a portion of a display panel according to some embodiments; and

FIG. 16 is a cross-sectional view schematically illustrating a portion of a display apparatus according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in more detail with reference to the drawings. However, embodiments according to the present disclosure are not limited to the following embodiments and may be embodied in various forms.

In the following embodiments, although the terms “first,” “second,” etc., may be used to describe various elements, such elements should not be limited to the above terms. The above terms are used to distinguish one element from another.

In the following embodiments, an expression used in the singular encompasses the expression of the plural, unless it has a clearly different meaning in the context.

In the following embodiments, the terms “comprise,” “comprising,” “include” and/or “including” are used to specify the presence of stated features or elements, but do not preclude the addition of one or more other features or elements.

In the following embodiments, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of description. For example, because sizes and thicknesses of elements in the drawings are arbitrarily illustrated for convenience of description, the disclosure is not limited thereto.

As used herein, the expression “A and/or B” means only A, only B, or both A and B. As used herein, the expression “at least one of A and B” means A or B, or A and B.

In the following embodiments, when a wiring is referred to as “extending in a first direction or a second direction,” it means that the wiring not only extends in a straight line shape but also extends in a zigzag or in a curve in the first direction or the second direction.

In the following embodiments, the expression “in a plan view” means that an objective portion is viewed from above, and the expression “in a cross-sectional view” means that a cross-section of an objective portion taken vertically is viewed from a lateral side. In the following embodiments, the expression “overlapping” includes overlapping “in a plan view” and “in a cross-sectional view.”

Hereinafter, aspects of some embodiments of the disclosure are described in more detail with reference to the accompanying drawings. When describing the drawings, like reference numerals are used for like or corresponding elements.

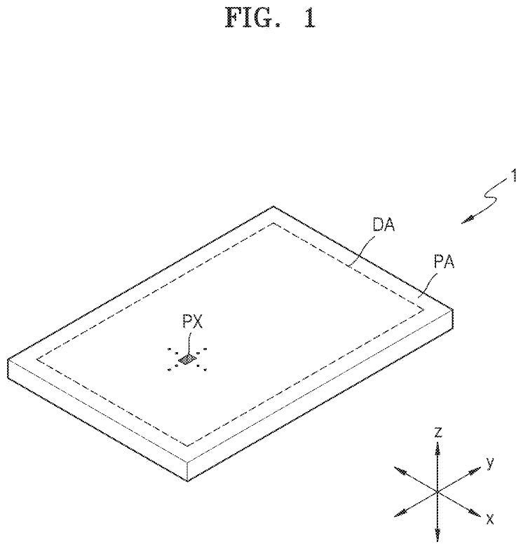

FIG. 1 is a perspective view schematically illustrating a display apparatus according to some embodiments.

According to some embodiments, a display apparatus 1 is an apparatus for displaying moving images (e.g., video images) or still images (e.g., static images), and may be used as a display screen of various products including not only portable devices, such as a mobile phone, a smartphone, a tablet personal computer, a mobile communication terminal, an electronic notebook, an electronic book, a portable multimedia player (PMP), a navigation device, and an ultra-mobile personal computer (UMPC), but also other devices, such as a television, a laptop computer, a monitor, a billboard, and an Internet of things (IOT) device.

Also, according to some embodiments, the display apparatus 1 may be used in a wearable device, such as a smart watch, a watch phone, a glasses-type display, and a head-mounted display (HMD). Also, according to some embodiments, the display apparatus 1 may be used as a vehicle instrument panel, a center information display (CID) located on a center fascia or a dashboard of a vehicle, a room mirror display replacing a side mirror of a vehicle, or a display located on a rear surface of a front seat as an entertainment for a back seat of a vehicle. For convenience of description, FIG. 1 shows that the display apparatus 1 is used as a smartphone.

Referring to FIG. 1, the display apparatus 1 may include a display area DA and a peripheral area PA outside of the display area DA. That is, the peripheral area PA may be outside a footprint (or in a periphery of) the display area DA. Although FIG. 1 shows that the display area DA has a substantially rectangular shape, embodiments according to the disclosure are not limited thereto. The display area DA may be provided in various shapes, such as a circle, an ellipse, and a polygon.

The display area DA is an area at which images are displayed, and a plurality of sub-pixels PX may be arranged in the display area DA. Each sub-pixel PX may include a light-emitting device, such as an organic light-emitting diode. Each sub-pixel PX may emit, for example, red, green, blue, or white light.

The display area DA may provide a certain image through the light emitted from the sub-pixels PX. As used herein, the sub-pixel PX may be defined as an emission area emitting one of red, green, blue, and white light, as described above.

The peripheral area PA is an area in which the sub-pixels PX are not arranged, and may be an area that provides no image. A printed circuit board including a power supply wiring and a driving circuit portion for driving the sub-pixels PX or a terminal portion to which a driver integrated circuit (IC) is connected may be arranged in the peripheral area PA.

Hereinafter, an organic light-emitting display apparatus will be described as the display apparatus 1 according to some embodiments. However, the display apparatus 1 of the disclosure is not limited thereto. For example, the display apparatus 1 of the disclosure may be an inorganic light-emitting display apparatus (or an inorganic electroluminescent display apparatus) or a quantum dot light-emitting display apparatus. For example, an emission layer included in a light-emitting diode included in the display apparatus 1 may include an organic material or an inorganic material. Also, quantum dots may be arranged on a path of light emitted from the emission layer.

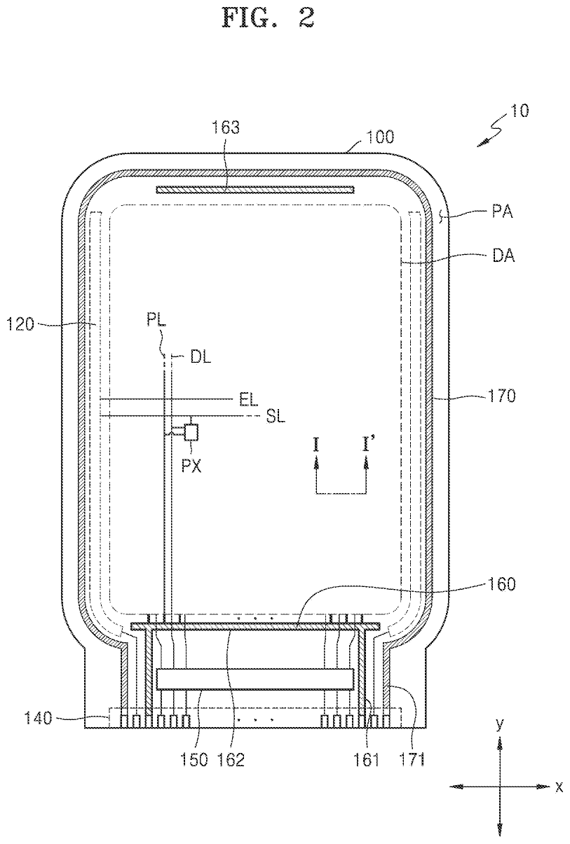

FIG. 2 is a plan view schematically illustrating a display panel provided in a display apparatus, according to some embodiments.

Referring to FIG. 2, the display apparatus 1 may include a display panel 10 that is a panel on which an image is displayed. The display panel 10 may include the plurality of sub-pixels PX arranged in the display area DA. Each of the sub-pixels PX may be electrically connected to external circuits arranged in the peripheral area PA. A driving circuit 120, a pad portion 140, a data driving circuit 150, a first power supply wiring 160, and a second power supply wiring 170 may be arranged in the peripheral area PA.

The driving circuit 120 may provide a scan signal to each sub-pixel PX through a scan line SL, and may provide an emission control signal to each sub-pixel PX through an emission control line EL. Some of the plurality of sub-pixels PX arranged in the display area DA may be electrically connected to at least one of the driving circuits 120 provided on left and right sides of the display area DA. The pad portion 140 may be arranged on one side of a substrate 100. The pad portion 140 may be exposed without being covered by an insulating layer, and may be electrically connected to a printed circuit board. The pad portion 140 may be electrically connected to a pad portion of the printed circuit board. The printed circuit board may transmit a signal or power of a controller to the display panel 10.

Control signals generated by the controller may be respectively transmitted to the driving circuits 120 provided on left and right sides of the display area DA through the printed circuit board. The controller may provide a first power voltage to the first power supply wiring 160 through a first connection line 161, and may provide a second power voltage to the second power supply wiring 170 through a second connection line 171.

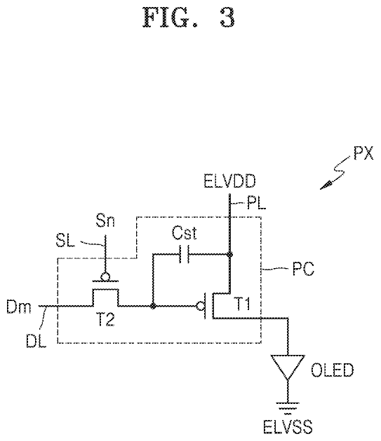

The first power voltage may be provided to each sub-pixel PX through a driving voltage line PL connected to the first power supply wiring 160, and the second power voltage may be provided to an opposite electrode of each sub-pixel PX connected to the second power supply wiring 170. The driving voltage line PL may extend in a y-direction. For example, the first power voltage may be a driving voltage ELVDD (see FIG. 3), and the second power voltage may be a common voltage ELVSS (see FIG. 3).

The data driving circuit 150 may be electrically connected to a data line DL. A data signal of the data driving circuit 150 may be provided to each sub-pixel PX through a connection wiring connected to the pad portion 140 and the data line DL connected to the connection wiring. Although FIG. 2 shows that the data driving circuit 150 is arranged between the first power supply wiring 160 and the pad portion 140 on the substrate 100, according to some embodiments, the data driving circuit 150 may be located on the printed circuit board.

The first power supply wiring 160 may include, for example, a first sub-wiring 162 and a second sub-wiring 163 that extend parallel to each other in an x-direction with the display area DA therebetween. The second power supply wiring 170 may have a loop shape having an open side, and may partially surround the display area DA.

FIG. 3 is an equivalent circuit diagram schematically illustrating a light-emitting diode of a display panel and a sub-pixel circuit electrically connected thereto, according to some embodiments.

Referring to FIG. 3, each sub-pixel PX may include a sub-pixel circuit PC connected to the scan line SL and the data line DL, and an organic light-emitting diode OLED connected to the sub-pixel circuit PC. The sub-pixel circuit PC may include a driving thin-film transistor T1, a switching thin-film transistor T2, and a storage capacitor Cst. The switching thin-film transistor T2 may be connected to the scan line SL and the data line DL, and may be configured to transmit a data signal Dm input through the data line DL to the driving thin-film transistor T1 according to a scan signal Sn input through the scan line SL.

The storage capacitor Cst may be connected to the switching thin-film transistor T2 and the driving voltage line PL, and may be configured to store a voltage corresponding to a difference between a voltage received from the switching thin-film transistor T2 and the first power voltage (e.g., driving voltage ELVDD) supplied to the driving voltage line PL.

The driving thin-film transistor T1 may be connected to the driving voltage line PL and the storage capacitor Cst, and may be configured to control a driving current flowing from the driving voltage line PL to the organic light-emitting diode OLED, according to a value of the voltage stored in the storage capacitor Cst. The organic light-emitting diode OLED may emit light having a certain luminance according to the driving current.

Although FIG. 3 shows that the sub-pixel circuit PC includes two thin-film transistors and one storage capacitor, the disclosure is not limited thereto. For example, according to some embodiments, the sub-pixel circuit PC may include seven thin-film transistors and one or two storage capacitors.

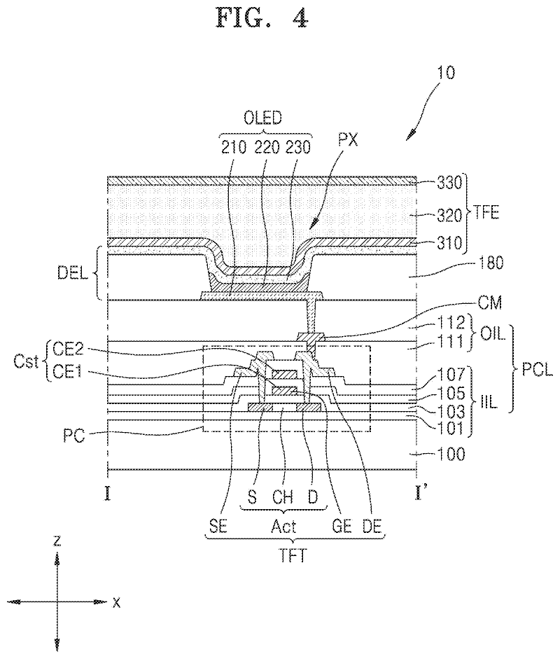

FIG. 4 is a cross-sectional view of the display panel 10 taken along a line I-I′ of FIG. 2. For example, FIG. 4 is a diagram illustrating a stacked structure of the sub-pixels PX of the display panel 10 according to some embodiments.

Referring to FIG. 4, the display panel 10 may include the substrate 100, a sub-pixel circuit layer PCL, a light-emitting diode layer DEL, and an encapsulation layer TFE.

The substrate 100 may include glass or polymer resin. The polymer resin may include polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 including the polymer resin may be flexible, rollable, or bendable. The substrate 100 may have a multi-layered structure including a layer including the above-described polymer resin and an inorganic layer.

The sub-pixel circuit layer PCL may be located on the substrate 100. The sub-pixel circuit layer PCL may include the sub-pixel circuit PC, an inorganic insulating layer IIL, and an organic insulating layer OIL. According to some embodiments, the inorganic insulating layer IIL may include a buffer layer 101, a gate insulating layer 103, a first interlayer insulating layer 105, and a second interlayer insulating layer 107. According to some embodiments, the organic insulating layer OIL may include a first organic insulating layer 111 and a second organic insulating layer 112.

The sub-pixel circuit layer PCL may include thin-film transistors and a capacitor. In this regard, FIG. 4 shows a thin-film transistor TFT and the storage capacitor Cst. The thin-film transistor TFT may correspond to one of the thin-film transistors provided in the sub-pixel circuit PC described with reference to FIG. 3, for example, the driving thin-film transistor T1. The thin-film transistor TFT may include a semiconductor layer Act, a gate electrode GE, a source electrode SE, and a drain electrode DE.

The buffer layer 101 may be located on the substrate 100 to reduce or block penetration of foreign materials, moisture, or ambient air from below the substrate 100, and may provide a flat surface on the substrate 100. The buffer layer 101 may include an inorganic material, such as oxide or nitride, an organic material, or an organic-inorganic composite material, and may have a single-layered or multi-layered structure including an inorganic material and an organic material.

The semiconductor layer Act may include a channel area CH, a source area S, and a drain area D, the channel area CH overlapping the gate electrode GE, and the source area S and the drain area D being arranged on both sides of the channel area CH and including impurities at a higher concentration than the channel area CH. In this regard, the impurities may include N-type impurities or P-type impurities. The source area S and the drain area D may be electrically and respectively connected to the source electrode SE and the drain electrode DE of the thin-film transistor TFT.

The semiconductor layer Act may include an oxide semiconductor and/or a silicon semiconductor. When the semiconductor layer Act includes an oxide semiconductor, the semiconductor layer Act may include, for example, an oxide of at least one material selected from among indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the semiconductor layer Act may include InSnZnO (ITZO), InGaZnO (IGZO), etc. When the semiconductor layer Act includes a silicon semiconductor, the semiconductor layer Act may include, for example, amorphous silicon or low-temperature polysilicon (LAPS) obtained by crystallizing the amorphous silicon.

The gate electrode GE may include a conductive material including molybdenum (Mo), aluminum (Al), copper (Cu), titanium (Ti), etc., and may be formed as a multi-layer or single layer including the above-described material. The gate electrode GE may be connected to a gate line configured to apply an electrical signal to the gate electrode GE.

The gate insulating layer 103 may be arranged between the semiconductor layer Act and the gate electrode GE to insulate the semiconductor layer Act from the gate electrode GE. The gate insulating layer 103 may include at least one inorganic insulating material selected from among silicon oxide, silicon nitride, silicon oxynitride, aluminum oxide, titanium oxide, tantalum oxide, hafnium oxide, and zinc oxide. The gate insulating layer 103 may have a single-layered or multi-layered structure including the above-described inorganic insulating material.

The storage capacitor Cst may include a first capacitor electrode CE1 and a second capacitor electrode CE2 located on the first capacitor electrode CE1. The first capacitor electrode CE1 and the second capacitor electrode CE2 of the storage capacitor Cst may overlap each other. According to some embodiments, the gate electrode GE of the thin-film transistor TFT may include the first capacitor electrode CE1 of the storage capacitor Cst.

The first interlayer insulating layer 105 may be arranged between the first capacitor electrode CE1 and the second capacitor electrode CE2. The first interlayer insulating layer 105 may include an inorganic insulating material, such as silicon oxide, silicon nitride, silicon oxynitride, aluminum oxide, titanium oxide, tantalum oxide, hafnium oxide, and/or zinc oxide, and may have a single-layered or multi-layered structure including the inorganic insulating material.

Although FIG. 4 shows that the storage capacitor Cst overlaps the thin-film transistor TFT, and the first capacitor electrode CE1 is integrally formed as a single body with the gate electrode GE of the thin-film transistor TFT, according to some embodiments, the storage capacitor Cst may not overlap the thin-film transistor TFT, and the first capacitor electrode CE1 may be a separate element independent from the gate electrode GE of the thin-film transistor TFT.

The second interlayer insulating layer 107 may be located on the second capacitor electrode CE2 of the storage capacitor Cst. The second interlayer insulating layer 107 may include at least one inorganic insulating material selected from among silicon oxide, silicon nitride, silicon oxynitride, aluminum oxide, titanium oxide, tantalum oxide, hafnium oxide, and zinc oxide. The second interlayer insulating layer 107 may have a single-layered or multi-layered structure including the above-described material.

The source electrode SE and the drain electrode DE may be located on the second interlayer insulating layer 107. The source electrode SE and the drain electrode DE may include, for example, a material such as Mo, Al, Cu, and/or Ti, and may have a single-layered or multi-layered structure including the above-described material. The source electrode SE and the drain electrode DE may have a multi-layered structure of Ti/Al/Ti. According to some embodiments, the source electrode SE and the drain electrode DE may include the same material as the first power supply wiring 160 and the second power supply wiring 170.

The light-emitting diode layer DEL may be located on the sub-pixel circuit layer PCL. The light-emitting diode layer DEL may include, for example, the organic light-emitting diode OLED as a light-emitting device.

The organic light-emitting diode OLED may be electrically connected to the sub-pixel circuit PC. The organic light-emitting diode OLED may be electrically connected to the sub-pixel circuit PC to implement the sub-pixel PX. The organic light-emitting diode OLED may include a sub-pixel electrode 210, an emission layer 220, and an opposite electrode 230.

The sub-pixel electrode 210 may be electrically connected to the sub-pixel circuit PC. According to some embodiments, as shown in FIG. 4, the sub-pixel circuit PC may be electrically connected to the sub-pixel electrode 210 through a connection electrode CM. According to some embodiments, an additional connection electrode may be further arranged between the sub-pixel circuit PC and the sub-pixel electrode 210. In this case, the sub-pixel circuit PC may be electrically connected to the sub-pixel electrode 210 through the connection electrode CM and the additional connection electrode. Alternatively, the sub-pixel circuit PC may be directly electrically connected to the sub-pixel electrode 210 without the connection electrode CM.

The connection electrode CM may be located on the first organic insulating layer 111, and may be connected to the sub-pixel circuit PC through a contact hole formed in the first organic insulating layer 111. The connection electrode CM may include a conductive material including Mo, Al, Cu, Ti, etc. Alternatively, the connection electrode CM may include a transparent conductive material, for example, a transparent conducting oxide (TCO). The connection electrode CM may have a single-layered or multi-layered structure including the above-described material.

The first organic insulating layer 111 may include an organic material. For example, the first organic insulating layer 111 may include an organic insulating material including a general-purpose polymer, such as polymethylmethacrylate (PMMA) or polystyrene (PS), a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and a blend thereof.

The second organic insulating layer 112 may be located on the connection electrode CM. The second organic insulating layer 112 may include an organic material. For example, the second organic insulating layer 112 may include an organic insulating material, such as acryl, benzocyclobutene (BCB), polyimide, or hexamethyldisiloxane (HMDSO).

The sub-pixel electrode 210 may include a reflective layer including silver (Ag), magnesium (Mg), Al, platinum (Pt), palladium (Pd), gold (Au), nickel (Ni), neodymium (Nd), iridium (Ir), Cr, or a compound thereof. Alternatively, the sub-pixel electrode 210 may further include a conductive oxide material layer on and/or under the reflective layer. The conductive oxide material layer may include indium tin oxide (ITO), indium zinc oxide (IZO), zinc oxide (ZnO), indium oxide (In₂O₃), indium gallium oxide (IGO), and/or aluminum zinc oxide (AZO). According to some embodiments, the sub-pixel electrode 210 may have a three-layered structure of ITO/Ag/ITO.

A bank layer 180 may be located on the sub-pixel electrode 210. The bank layer 180 may have an opening through which a central portion of the sub-pixel electrode 210 is exposed. The opening of the bank layer 180 may define an emission area of the organic light-emitting diode OLED, and the emission area of the organic light-emitting diode OLED may correspond to the sub-pixel PX. Also, the bank layer 180 may prevent or reduce instances of an arc, etc., occurring at an edge of the sub-pixel electrode 210 by increasing a distance between the edge of the sub-pixel electrode 210 and the opposite electrode 230 above the sub-pixel electrode 210.

The bank layer 180 may include an organic insulating material. According to some embodiments, the bank layer 180 may include an inorganic insulating material, such as silicon nitride, silicon oxynitride, or silicon oxide. According to some embodiments, the bank layer 180 may include an organic insulating material and an inorganic insulating material. In some embodiments, the bank layer 180 may include a light-blocking material, and may have a black color. The light-blocking material may include carbon black, carbon nanotubes, resin or paste including black dye, metal particles, for example, Ni, Al, Mo, and an alloy thereof, metal oxide particles (e.g., chrome oxide) or metal nitride particles (e.g., chrome nitride).

A spacer may be located on the bank layer 180. The spacer may prevent or reduce instances of the organic light-emitting diode OLED being damaged due to sagging of a mask in a manufacturing process using the mask.

The emission layer 220 may be located on the sub-pixel electrode 210. The emission layer 220 may overlap the opening of the sub-pixel electrode 210. The emission layer 220 may include a low-molecular weight material or a high-molecular weight material, and may emit red, green, blue, or white light.

A functional layer may be optionally further located below and above the emission layer 220. For example, a hole injection layer (HIL) and/or a hole transport layer (HTL) may be arranged between the emission layer 220 and the sub-pixel electrode 210. Also, an electron transport layer (ETL) and/or an electron injection layer (EIL) may be arranged between the emission layer 220 and the opposite electrode 230.

According to some embodiments, the emission layer 220 may be patterned to correspond to each of a plurality of sub-pixel electrodes 210. In some embodiments, the emission layer 220 may be integrally formed as a single body over the plurality of sub-pixel electrodes 210. According to some embodiments, the functional layer located below and above the emission layer 220 may be integrally formed as a single body over the plurality of sub-pixel electrodes 210.

The opposite electrode 230 may be located on the emission layer 220. According to some embodiments, the opposite electrode 230 may entirely cover the display area DA. That is, the opposite electrode 230 may be integrally formed as a single body to cover the plurality of sub-pixels PX.

The opposite electrode 230 may include a conductive material having a low work function. For example, the opposite electrode 230 may include a (semi) transparent layer including Ag, Mg, Al, Pt, Pd, Au, Ni, Nd, Ir, Cr, lithium (Li), calcium (Ca), or an alloy thereof. Alternatively, the opposite electrode 230 may further include a layer including ITO, IZO, ZnO, or In₂O₃ on the (semi) transparent layer including the above-described material.

The sub-pixel circuit layer PCL and the light-emitting diode layer DEL may be covered with an encapsulation member. The encapsulation member may include the encapsulation layer TFE or an encapsulation substrate, such as a glass substrate. The encapsulation member may protect the organic light-emitting diode OLED from external moisture and oxygen.

The encapsulation layer TFE may include at least one organic encapsulation layer and at least one inorganic encapsulation layer. The encapsulation layer TFE may cover the entire display area DA, and may extend toward the peripheral area PA to cover a portion of the peripheral area PA.

The encapsulation layer TFE may include a first inorganic encapsulation layer 310, a second inorganic encapsulation layer 330 located on the first inorganic encapsulation layer 310, and an organic encapsulation layer 320 arranged between the first inorganic encapsulation layer 310 and the second inorganic encapsulation layer 330. Each of the first inorganic encapsulation layer 310 and the second inorganic encapsulation layer 330 may include at least one inorganic insulating material. The inorganic insulating material may include aluminum oxide, titanium oxide, tantalum oxide, hafnium oxide, zinc oxide, silicon oxide, silicon nitride, and/or silicon oxynitride.

The organic encapsulation layer 320 may include a polymer-based material. The polymer-based material may include acrylic-based resin, epoxy-based resin, polyimide, and polyethylene. The organic encapsulation layer 320 may include acrylic-based resin, for example, poly (methyl methacrylate), polyacrylic acid, etc. The organic encapsulation layer 320 may be formed by curing a monomer or coating a polymer.

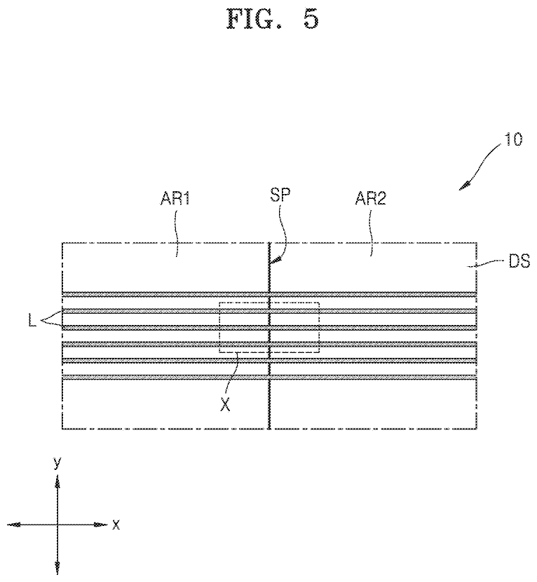

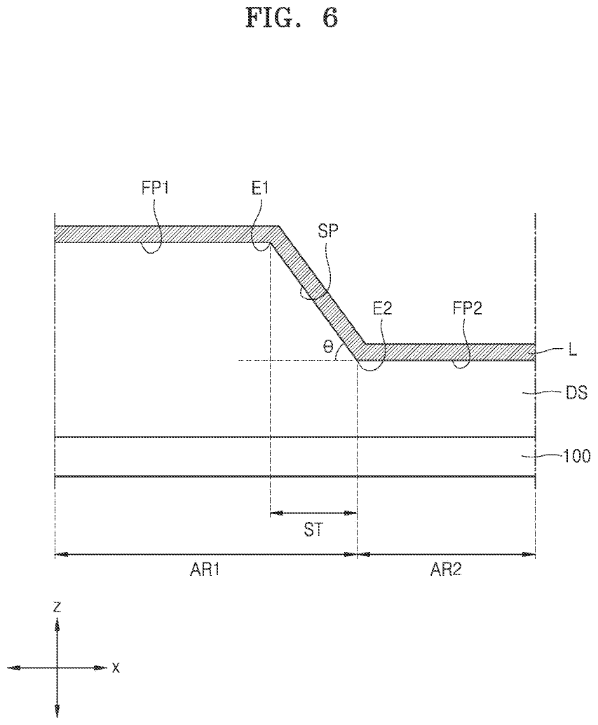

FIG. 5 is a plan view schematically illustrating a portion of a display panel according to some embodiments, and FIG. 6 is a cross-sectional view schematically illustrating a portion of a display panel according to some embodiments.

Referring to FIG. 5, the display panel 10 may include a first area AR1 and a second area AR2. For example, it may be understood that the substrate 100 included in the display panel 10 includes the first area AR1 and the second area AR2. The first area AR1 and the second area AR2 may be adjacent to each other.

According to some embodiments, the first area AR1 and the second area AR2 may be arranged in the display area DA. However, the disclosure is not limited thereto. According to some embodiments, one of the first area AR1 and the second area AR2 may be arranged in the display area DA, and the other one may be arranged in the peripheral area PA. Alternatively, the first area AR1 and the second area AR2 may be arranged in the peripheral area PA.

Referring to FIGS. 5 and 6, the display panel 10 may include a lower layer DS on the substrate 100 and a plurality of wirings L located on the lower layer DS.

The lower layer DS may be arranged over the first area AR1 and the second area AR2 of the substrate 100. An upper surface of the lower layer DS may include a first surface portion FP1 arranged in the first area AR1 and a second surface portion FP2 arranged in the second area AR2. The first surface portion FP1 and the second surface portion FP2 may have relatively flat surfaces. For example, according to some embodiments, the first surface portion FP1 and the second surface portion FP2 may be substantially parallel to an upper surface of the substrate 100. A vertical distance from the upper surface of the substrate 100 to the second surface portion FP2 may be smaller than a vertical distance from the upper surface of the substrate 100 to the first surface portion FP1. The upper surface of the lower layer DS may have a step between the first surface portion FP1 and the second surface portion FP2. The first area AR1 may include a step area ST provided at a boundary with the second area AR2.

The upper surface of the lower layer DS may include an inclined surface portion SP arranged between the first surface portion FP1 and the second surface portion FP2. The inclined surface portion SP may be arranged in the step area ST. One edge of the inclined surface portion SP may correspond to a boundary between the first area AR1 and the second area AR2. The inclined surface portion SP may be inclined downward with respect to the first surface portion FP1. The inclined surface portion SP may be inclined in a direction away from the first surface portion FP1, or in a direction toward the second surface portion FP2. The inclined surface portion SP may have a vertical distance that is smaller than a vertical distance from the substrate 100 to the first surface portion FP1 and greater than a vertical distance from the substrate 100 to the second surface portion FP2.

According to some embodiments, the first surface portion FP1, the inclined surface portion SP, and the second surface portion FP2 may be continuously arranged. The first surface portion FP1 and the inclined surface portion SP may be connected to each other, and the inclined surface portion SP and the second surface portion FP2 may be connected to each other. The first surface portion FP1, the inclined surface portion SP, and the second surface portion FP2 may be connected to each other to form a stepped structure. In this case, a boundary line between the first surface portion FP1 and the inclined surface portion SP may correspond to a first edge E1 of the inclined surface portion SP, and a boundary line between the inclined surface portion SP and the second surface portion FP2 may correspond to a second edge E2 of the inclined surface portion SP.

An angle θ of the inclined surface portion SP with respect to the upper surface of the substrate 100 may be an acute angle or a right angle. Although FIG. 6 shows that the angle θ of the inclined surface portion SP with respect to the upper surface of the substrate 100 is an acute angle, the disclosure is not limited thereto.

The lower layer DS may include at least one layer. Although FIG. 6 shows that the lower layer DS is provided as one layer, the disclosure is not limited thereto. The lower layer DS may include a plurality of sub-layers. According to some embodiments, each of the sub-layers of the lower layer DS may be, for example, arranged on the same layer and include the same material as at least one of the insulating layers of the sub-pixel circuit layer PCL described above with reference to FIG. 4.

The plurality of wirings L may be located on the lower layer DS. The plurality of wirings L may extend in a first direction (e.g., an x-direction) from the first area AR1 toward the second area AR2. The plurality of wirings L may be spaced apart from each other. The plurality of wirings L may pass through the step area ST. That is, the plurality of wirings L may be located on the inclined surface portion SP of the lower layer DS.

According to some embodiments, the plurality of wirings L may be arranged on the same layer, and may include the same material. The plurality of wirings L may be directly located on the lower layer DS. The plurality of wirings L may include the same material as a metal layer included in the sub-pixel circuit layer PCL described with reference to FIG. 4. For example, the plurality of wirings L may include the same material as the connection electrode CM.

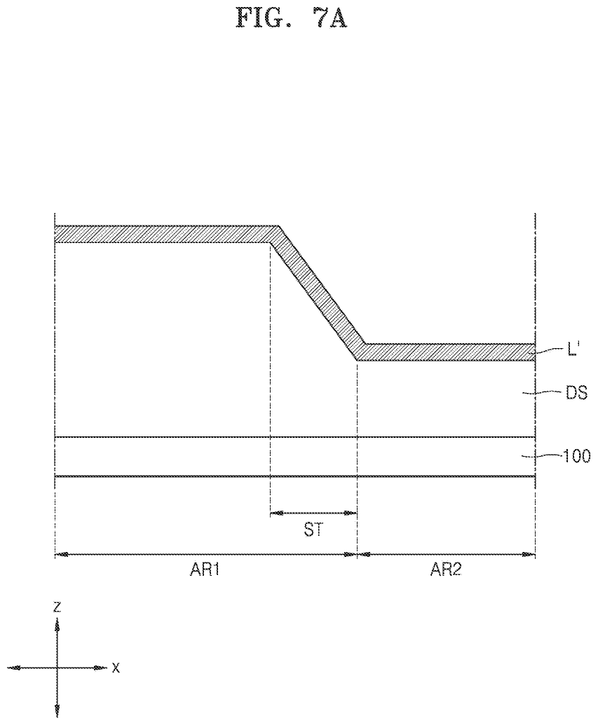

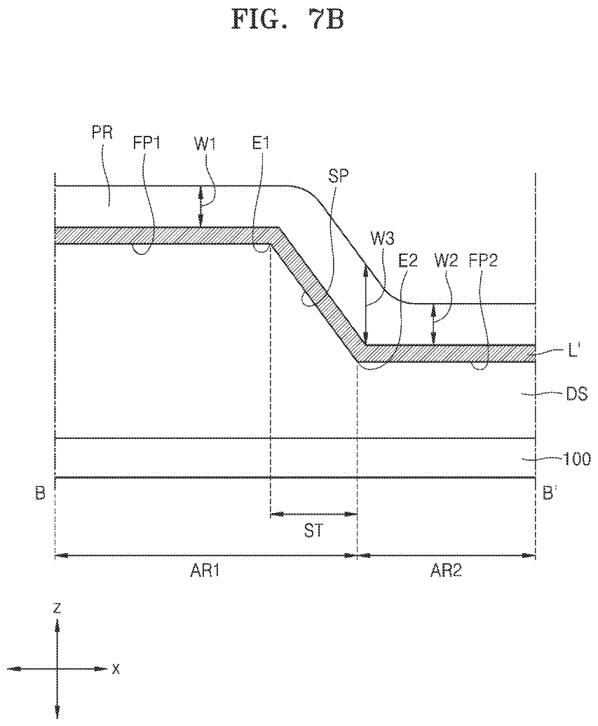

FIGS. 7A and 7B are cross-sectional views illustrating a method of manufacturing a display panel, according to some embodiments, and show a process of forming the wiring L of FIG. 6.

Referring to FIGS. 7A and 7B, the wiring L may be formed by a photolithography process. First, a conductive layer L′ may be formed on the lower layer DS, and a photoresist pattern PR may be formed on the conductive layer L′ to correspond to a portion in which the wiring L is to be formed. The photoresist pattern PR may be formed by coating a photoresist layer and performing an exposure and development process. Then, the wiring L may be formed by etching and removing a portion of the conductive layer L′ by using the photoresist pattern PR as a mask.

Referring to FIG. 7B, in the process of forming the photoresist pattern PR, due to the fluidity of a photoresist, the photoresist pattern PR may be relatively thickly formed on the inclined surface portion SP of the lower layer DS corresponding to the step area ST. For example, a thickness W3 of a portion of the photoresist pattern PR located on the inclined surface portion SP may be greater than a thickness W1 of a portion of the photoresist pattern PR located on the first surface portion FP1 and a thickness W2 of a portion of the photoresist pattern PR located on the second surface portion FP2. In the inclined surface portion SP, the photoresist pattern PR may be formed to have an increasing thickness from a vicinity of the first edge E1, which is far from the substrate 100, toward a vicinity of the second edge E2, which is close to the substrate 100.

When etching is performed under the same etching conditions, the width of the wiring L on a portion on which the photoresist pattern PR is relatively thick may be formed to be greater than the width of the wiring L on a portion on which the photoresist pattern PR is relatively thin. Accordingly, the width of the wiring L on the inclined surface portion SP may be formed to be greater than the width of the wiring L on the first surface portion FP1 and the second surface portion FP2. In particular, the width of the wiring L may be formed to be the greatest in the vicinity of the second edge E2 of the inclined surface portion SP. In this case, the width of the wiring L may increase in a direction in which the inclined surface portion SP extends. For example, the width of the wiring L arranged at the second edge E2 may increase in a direction in which the second edge E2 extends.

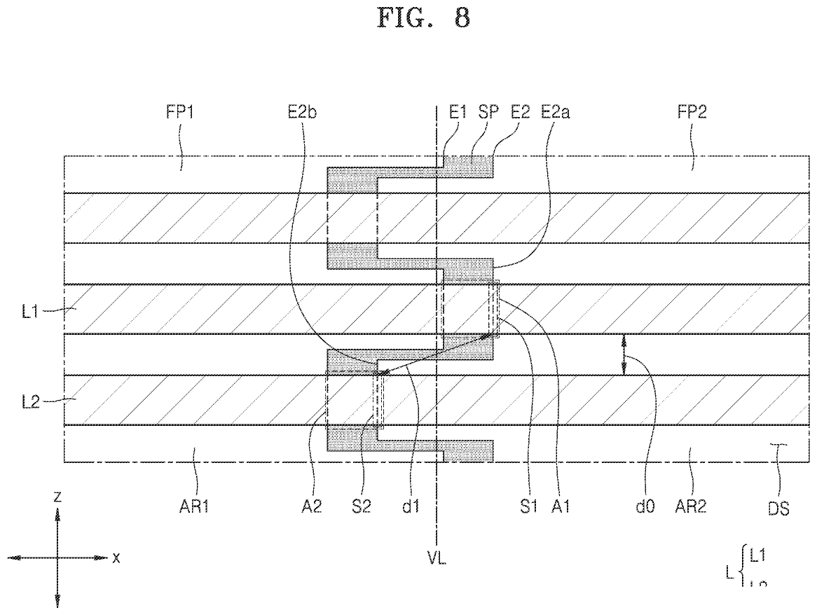

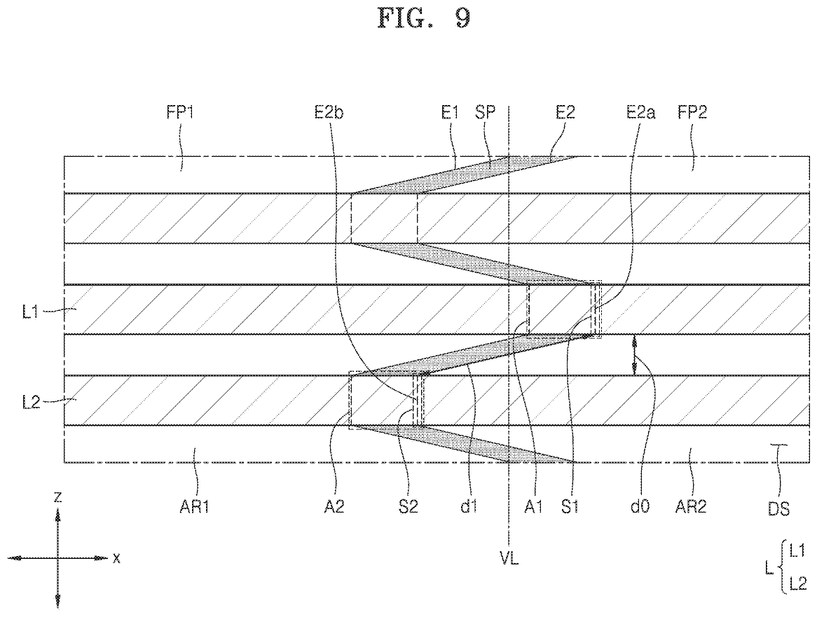

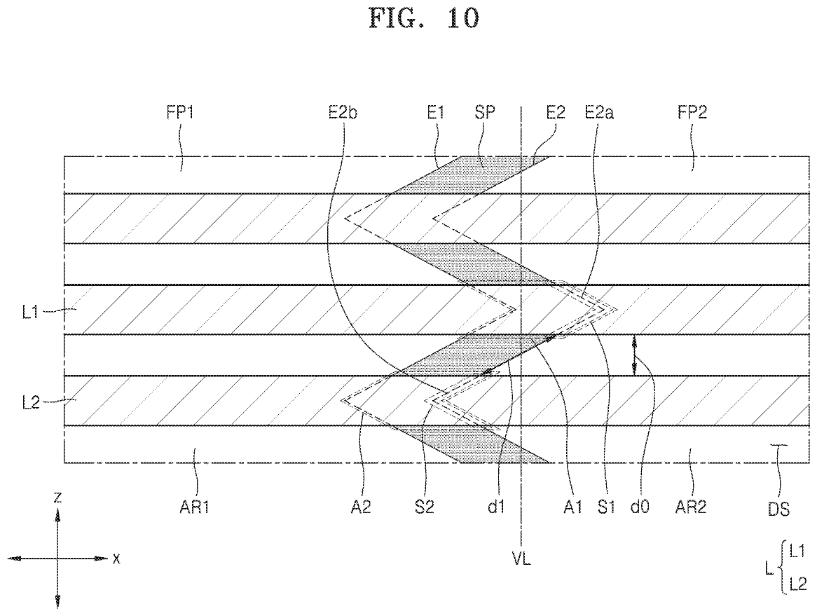

FIG. 8 is a plan view schematically illustrating a portion of a display panel according to some embodiments, and is an enlarged plan view of a region X of FIG. 5. FIG. 9 is a plan view schematically illustrating a portion of a display panel according to some embodiments, and FIG. 10 is a plan view schematically illustrating a portion of a display panel according to some embodiments.

Referring to FIG. 8, a plurality of wirings L may be located on the lower layer DS. The plurality of wirings L may include two adjacent wirings L. In this regard, FIG. 8 shows a first wiring L1 and a second wiring L2 that are adjacent to each other. The first wiring L1 and the second wiring L2 may extend in the first direction (e.g., the x-direction) from the first area AR1 toward the second area AR2. The first wiring L1 and the second wiring L2 may extend from the first surface portion FP1 of the lower layer DS to the second surface portion FP2 through the inclined surface portion SP. The first wiring L1 and the second wiring L2 may be apart from each other in a second direction (e.g., a y-direction) that is perpendicular to the first direction in which the wirings L extend.

The first wiring L1 may include a first inclined portion A1 overlapping the inclined surface portion SP, and the second wiring L2 may include a second inclined portion A2 overlapping the inclined surface portion SP. The first inclined portion A1 may include a first portion S1 overlapping the second edge E2 of the inclined surface portion SP. The second inclined portion A2 may include a second portion S2 overlapping the second edge E2 of the inclined surface portion SP.

In a plan view, the first inclined portion A1 of the first wiring L1 may be arranged in a diagonal direction crossing the first direction, in which the wiring L extends, with respect to the second inclined portion A2 of the second wiring L2. For example, based on the second edge E2 of the inclined surface portion SP, the first portion S1 of the first wiring L1 may be arranged in a diagonal direction crossing the first direction with respect to the second portion S2 of the second wiring L2. In this regard, the term “diagonal direction” may refer to a direction that is oblique to the first direction and the second direction. That is, the first portion S1 of the first wiring L1 and the second portion S2 of the second wiring L2 may be apart from each other in the first direction and the second direction.

Referring to FIGS. 8 to 10, according to some embodiments, in a plan view, the inclined surface portion SP of the lower layer DS may include an uneven shape in which a protruding portion and a recessed portion are repeatedly arranged. For example, in a plan view, the second edge E2 may have a shape in which a protruding portion E2a and a recessed portion E2b are repeatedly arranged. The protruding portion E2a may be a portion that protrudes in a direction toward the second area AR2 based on a virtual line VL, and the recessed portion E2b may be a portion that is recessed in a direction toward the first area AR1. The virtual line VL may be a straight line extending in the second direction.

One of the first wiring L1 and the second wiring L2 that are adjacent to each other may overlap the protruding portion of the inclined surface portion SP, and the other one may overlap the recessed portion of the inclined surface portion SP. In this regard, FIGS. 8 to 10 show that the first wiring L1 overlaps the protruding portion of the inclined surface portion SP, and the second wiring L2 overlaps the recessed portion of the inclined surface portion SP. For example, the first wiring L1 may overlap the protruding portion E2a of the second edge E2, and the second wiring L2 may overlap the recessed portion E2b of the second edge E2.

Referring to FIG. 8, the protruding portion E2a and the recessed portion E2b may each have a rectangular planar shape. However, the disclosure is not limited thereto. Referring to FIG. 9, according to some embodiments, the protruding portion E2a and the recessed portion E2b may each have a trapezoidal planar shape. Alternatively, referring to FIG. 10, according to some embodiments, the protruding portion E2a and the recessed portion E2b may each have a triangular planar shape. The first wiring L1 and the second wiring L2 may pass through vertices of each triangle. As described above, the shapes of the protruding portion E2a and the recessed portion E2b may be variously modified.

The first portion S1 in which the first wiring L1 overlaps the protruding portion E2a may be arranged in a diagonal direction crossing the first direction with respect to the second portion S2 in which the second wiring L2 overlaps the recessed portion E2b. That is, the first portion S1 of the first wiring L1 and the second portion S2 of the second wiring L2 may be apart from each other in the first direction and the second direction.

A separation distance d1 between the first portion S1 of the first wiring L1 and the second portion S2 of the second wiring L2 on the inclined surface portion SP may be greater than a separation distance d0 between the first wiring L1 and the second wiring L2 on the first surface portion FP1 or the second surface portion FP2. In this regard, the separation distance d1 corresponds to a separation distance between ends of the first portion S1 and the second portion S2. The separation distance d0 corresponds to a vertical separation distance between the first wiring L1 and the second wiring L2 on the first surface portion FP1 or the second surface portion FP2.

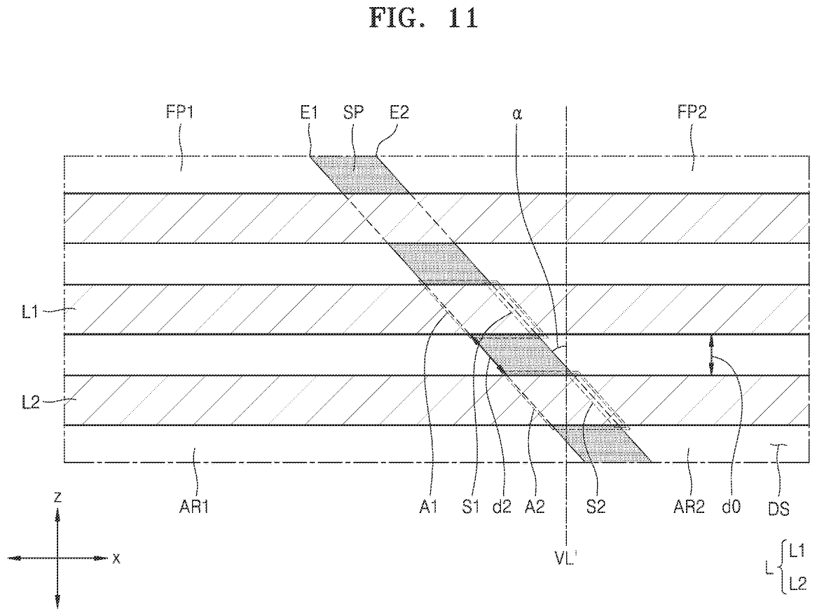

Referring to FIG. 11, according to some embodiments, in a plan view, the inclined surface portion SP of the lower layer DS may have an oblique shape that is inclined with respect to the first direction and the second direction. For example, based on the second edge E2 of the inclined surface portion SP, the second edge E2 may have an oblique shape that is inclined at a certain angle α with respect to a virtual line VL′. The virtual line VL′ may be a straight line extending in the second direction, and the certain angle α may be an acute angle or an obtuse angle.

The first portion S1 in which the first wiring L1 overlaps the second edge E2 of the inclined surface portion SP may be arranged in a diagonal direction crossing the first direction with respect to the second portion S2 in which the second wiring L2 overlaps the second edge E2 of the inclined surface portion SP. That is, the first portion S1 and the second portion S2 may be apart from each other in the first direction and the second direction. A separation distance d2 between the first portion S1 and the second portion S2 on the inclined surface portion SP may be greater than the separation distance d0 between the first wiring L1 and the second wiring L2 on the first surface portion FP1 or the second surface portion FP2.

In a comparative example, in a plan view, an inclined surface portion of a lower layer may include a linear shape extending in a second direction that is perpendicular to an extending direction of a wiring, rather than an uneven shape or an oblique shape. In this case, in a plan view, a first inclined portion in which a first wiring overlaps the inclined surface portion and a second inclined portion in which a second wiring overlaps the inclined surface portion may be arranged on the same line in the second direction. For example, a first portion in which the first wiring overlaps a second edge of the inclined surface portion and a second portion in which the second wiring overlaps the second edge of the inclined surface portion may be arranged on the same line in the second direction. Accordingly, a separation distance between the first portion of the first wiring and the second portion of the second wiring on the inclined surface portion may be the same as a separation distance between the first wiring and the second wiring on a first surface portion or a second surface portion.

As described above, in a photolithography process for forming a wiring, the width of the wiring on the inclined surface portion may be formed to be greater than the width of the wiring on the first surface portion and the second surface portion. In particular, the width of the wiring may be formed to be large in the first portion of the first wiring and the second portion of the second wiring. In the comparative example, because the separation distance between the first portion of the first wiring and the second portion of the second wiring according to the structure of a lower layer is the same as the separation distance between the first wiring and the second wiring on the first surface portion or the second surface portion, when the width of a wiring is formed to be large on the inclined surface portion due to process influences, a short circuit may occur as a distance between the first wiring and the second wiring adjacent to each other decreases.

However, according to one or more embodiments, by controlling the shape of the inclined surface portion SP of the lower layer DS, in a plan view, the first inclined portion A1 in which the first wiring L1 overlaps the inclined surface portion SP may be arranged in a diagonal direction crossing the first direction with respect to the second inclined portion A2 in which the second wiring L2 overlaps the inclined surface portion SP. For example, the first portion S1 in which the first wiring L1 overlaps the second edge E2 of the inclined surface portion SP may be arranged in a diagonal direction crossing the first direction with respect to the second portion S2 in which the second wiring L2 overlaps the second edge E2 of the inclined surface portion SP. Accordingly, the separation distances d1 and d2 between the first portion S1 and the second portion S2 on the inclined surface portion SP may be greater than the separation distance d0 between the first wiring L1 and the second wiring L2 on the first surface portion FP1 or the second surface portion FP2. Thus, according to some embodiments, even when the width of a wiring increases on the inclined surface portion SP, for example, in the first portion S1 and the second portion S2, due to process influences, a margin for preventing or reducing instances of a short circuit between wirings may be secured. Accordingly, the reliability of an apparatus may be relatively improved.

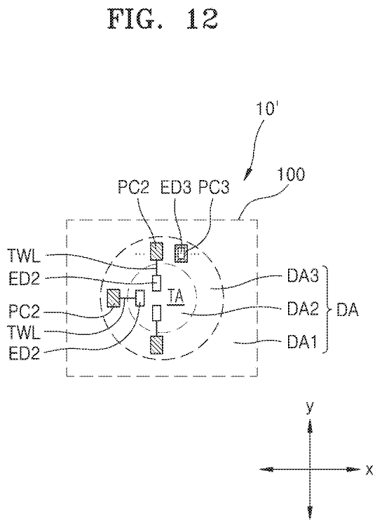

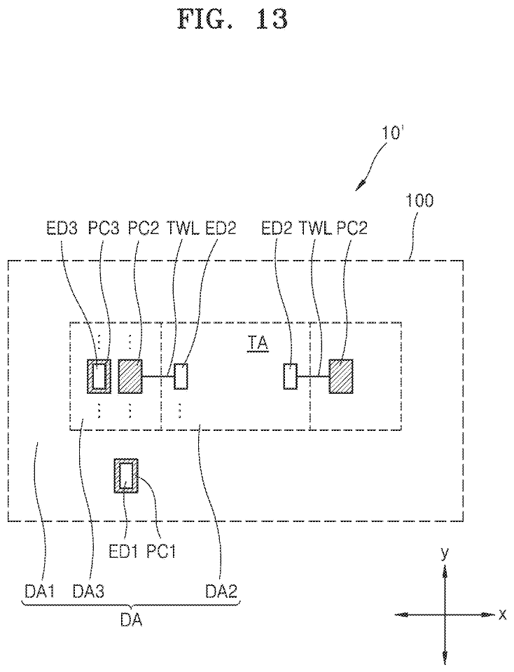

FIGS. 12 and 13 are plan views schematically illustrating a portion of a display panel according to some embodiments.

Referring to FIGS. 12 and 13, the display area DA of a display panel 10′ may include first to third display areas DA1 to DA3. As shown in FIG. 12, the third display area DA3 may entirely surround the second display area DA2. Alternatively, as shown in FIG. 13, the third display area DA3 may be arranged on one side of the second display area DA2. The first display area DA1 may at least partially surround the second display area DA2 and/or the third display area DA3.

Light-emitting diodes are arranged in the first to third display areas DA1 to DA3. Sub-pixel circuits electrically and respectively connected to the light-emitting diodes are arranged in the first display area DA1 and the third display area DA3, but not in the second display area DA2. For example, first sub-pixel circuits PC1 electrically connected to first light-emitting diodes ED1 arranged in the first display area DA1 may be arranged in the first display area DA1, and second and third sub-pixel circuits PC2 and PC3 electrically connected to second and third light-emitting diodes ED2 and ED3 arranged in the second display area DA2 and the third display area DA3 may be arranged in the third display area DA3. In other words, some of the sub-pixel circuits arranged in the third display area DA3 (e.g., the second sub-pixel circuit PC2) may be electrically connected to the second light-emitting diodes ED2 arranged in the second display area DA2, and some other of the sub-pixel circuits arranged in the third display area DA3 (e.g., the third sub-pixel circuit PC3) may be electrically connected to the third light-emitting diodes ED3 arranged in the third display area DA3. Hereinafter, for convenience of description, among the sub-pixel circuits arranged in the third display area DA3, sub-pixel circuits electrically connected to the second light-emitting diodes ED2 are referred to as the second sub-pixel circuits PC2, and among the sub-pixel circuits arranged in the third display area DA3, sub-pixel circuits electrically connected to the third light-emitting diodes ED3 are referred to as the third sub-pixel circuits PC3.

The first light-emitting diode ED1 is arranged in the first display area DA1. Light emitted from the first light-emitting diode ED1 may correspond to light of a corresponding first sub-pixel, and the position of the first light-emitting diode ED1 may be the position of the first sub-pixel. The first light-emitting diode ED1 may emit, for example, red, green, or blue light. The first sub-pixel circuit PC1 that drives the first light-emitting diode ED1 may be arranged in the first display area DA1, and may be electrically connected to the first light-emitting diode ED1.

The second light-emitting diode ED2 is arranged in the second display area DA2. Light emitted from the second light-emitting diode ED2 may correspond to light of a corresponding second sub-pixel, and the position of the second light-emitting diode ED2 may be the position of the second sub-pixel. The second light-emitting diode ED2 may emit, for example, red, green, or blue light.

A transmission area TA may be arranged between the second light-emitting diodes ED2. According to some embodiments, a region of the second display area DA2 in which the second light-emitting diodes ED2 are not arranged may correspond to the transmission area TA. To increase the area of the transmission area TA and improve the transmittance of the transmission area TA, the second sub-pixel circuit PC2 for driving the second light-emitting diode ED2 may be arranged in the third display area DA3 outside the second display area DA2. Some of the second sub-pixel circuits PC2 may be arranged in a partial area of the third display area DA3 adjacent to an upper side of the second display area DA2, and some of the second sub-pixel circuits PC2 may be arranged in a partial area of the third display area DA3 adjacent to a lower side of the second display area DA2. Alternatively, some of the second sub-pixel circuits PC2 may be arranged in a partial area of the third display area DA3 adjacent to a left or right side of the second display area DA2.

The second sub-pixel circuit PC2 in the third display area DA3 may be electrically connected to the second light-emitting diode ED2 in the second display area DA2 through a transparent conductive wiring TWL. The second light-emitting diode ED2 may be electrically connected to the second sub-pixel circuit PC2 through the transparent conductive wiring TWL.

The third light-emitting diode ED3 is arranged in the third display area DA3. Light emitted from the third light-emitting diode ED3 may correspond to light of a corresponding third sub-pixel, and the position of the third light-emitting diode ED3 may be the position of the third sub-pixel. The third light-emitting diode ED3 may emit, for example, red, green, or blue light.

The third sub-pixel circuit PC3 for driving the third light-emitting diode ED3 is arranged in the third display area DA3. The third sub-pixel circuit PC3 may be electrically connected to the third light-emitting diode ED3, and may operate the third light-emitting diode ED3.

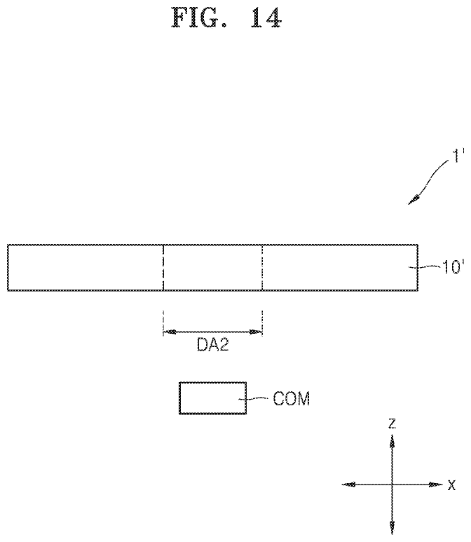

FIG. 14 is a plan view schematically illustrating a portion of a display apparatus according to some embodiments, and shows a display apparatus 1′ including the display panel 10′ of FIG. 13.

Referring to FIG. 14, the display apparatus 1′ may include the display panel 10′ and a component COM located below the display panel 10′.

The component COM may be an electronic element using light or sound. For example, the electronic element may be a sensor that measures a distance (e.g., a proximity sensor), a sensor that recognizes a body part of a user (e.g., a fingerprint, an iris, a face, etc.), a small lamp that outputs light, or an image sensor that captures an image (e.g., a camera). The electronic element using light may use light of various wavelength bands, such as visible light, infrared light, and ultraviolet light. The electronic element using sound may use ultrasonic waves or sound of other frequency bands.

The second display area DA2 may include the transmission area TA through which light and/or sound that is output from the component COM or traveling from the outside toward the component COM may be transmitted. In the display apparatus 1′ according to some embodiments, when light is transmitted through the second display area DA2 including the transmission area TA, a light transmittance may be 10% or more, in particular, 25% or more, 40% or more, 50% or more, 85% or more, or 90% or more.

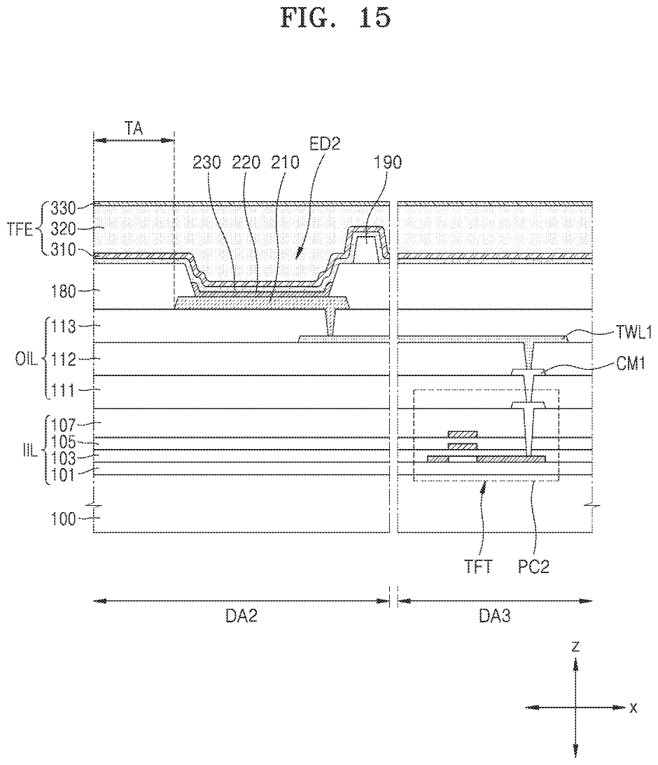

FIG. 15 is a cross-sectional view schematically illustrating a portion of a display panel according to some embodiments, and is a cross-sectional view illustrating an electrical connection between the second light-emitting diode ED2 and the second sub-pixel circuit PC2 of the display panel 10′ of FIG. 13.

Referring to FIG. 15, the second sub-pixel circuit PC2 on the substrate 100 may be arranged in the third display area DA3, and the second light-emitting diode ED2 electrically connected to the second sub-pixel circuit PC2 may be arranged in the second display area DA2. The second sub-pixel circuit PC2 may have the same structure as the sub-pixel circuit PC described above with reference to FIG. 4.

The inorganic insulating layer IIL and the organic insulating layer OIL may be located on the substrate 100. For example, inorganic insulating layers including the buffer layer 101, the gate insulating layer 103, the first interlayer insulating layer 105, and the second interlayer insulating layer 107, and organic insulating layers including the first organic insulating layer 111, the second organic insulating layer 112, and a third organic insulating layer 113 may be located on the substrate 100. The third organic insulating layer 113 may be located on the second organic insulating layer 112. The third organic insulating layer 113 may include an organic material. For example, the third organic insulating layer 113 may include an organic insulating material, such as acryl, BCB, polyimide, or HMDSO.

The second sub-pixel circuit PC2 may be electrically connected to the second light-emitting diode ED2 through a transparent conductive wiring TWL1 extending from the third display area DA3 toward the second display area DA2. For example, the transparent conductive wiring TWL1 may extend in the second direction (e.g., the y-direction). The transparent conductive wiring TWL1 may include a light-transmitting conductive material. The light-transmitting conductive material may include a TCO. The TCO may include a conductive oxide, such as ITO, IZO, ZnO, In₂O₃, IGO, indium zinc gallium oxide (IZGO), or AZO. Accordingly, a decrease in the light transmittance of the transmission area TA may be reduced.

The transparent conductive wiring TWL1 may be electrically connected to the thin-film transistor TFT of the second sub-pixel circuit PC2 through a first connection electrode CM1. The first connection electrode CM1 may be formed on the same layer and include the same material as the connection electrode CM (see FIG. 4). The transparent conductive wiring TWL1 may be electrically connected to the sub-pixel electrode 210 of the second light-emitting diode ED2 arranged in the second display area DA2. Although FIG. 15 shows that the sub-pixel electrode 210 of the second light-emitting diode ED2 is electrically connected to the transparent conductive wiring TWL1 through a contact hole of the third organic insulating layer 113, the disclosure is not limited thereto.

The bank layer 180 and a spacer 190 may be located on the sub-pixel electrode 210 of the second light-emitting diode ED2, the bank layer 180 having an opening overlapping the sub-pixel electrode 210. The spacer 190 may include an organic insulating material, such as polyimide. Alternatively, the spacer 190 may include an inorganic insulating material, such as silicon oxide, silicon nitride, or silicon oxynitride, or may include an organic insulating material and an inorganic insulating material. Also, as described above with reference to FIG. 4, the emission layer 220, the opposite electrode 230, and the encapsulation layer TFE may be located on the sub-pixel electrode 210.

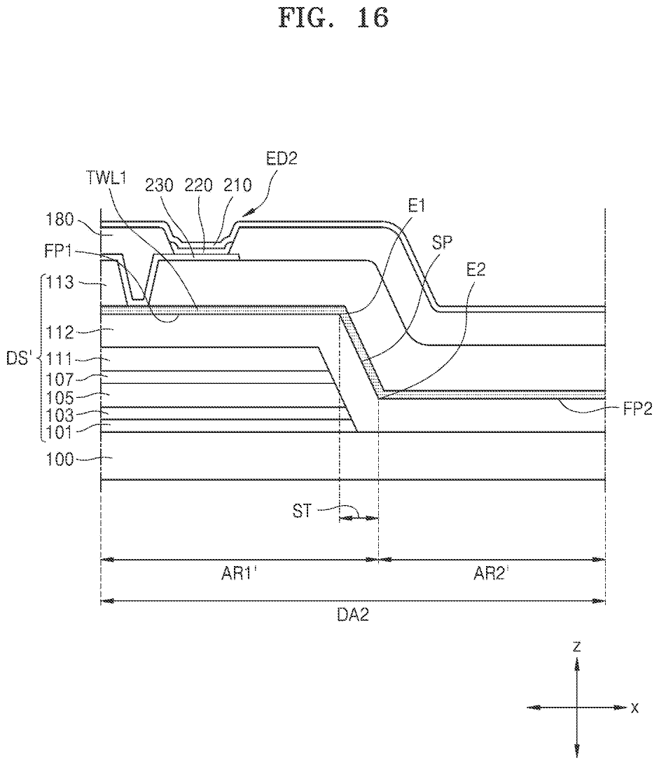

FIG. 16 is a cross-sectional view schematically illustrating a portion of a display apparatus according to some embodiments. FIG. 16 shows a portion of the second display area DA2 of the display panel 10′ shown in FIG. 13.

Referring to FIG. 16, the display panel 10′ may include a first area AR1′ and a second area AR2′. According to some embodiments, the first area AR1′ and the second area AR2′ may be included in the second display area DA2. The display panel 10′ may include the substrate 100, a lower layer DS' on the substrate 100, and the transparent conductive wiring TWL1 on the lower layer DS′. The lower layer DS' may be arranged over the first area AR1′ and the second area AR2′.

According to some embodiments, the lower layer DS' may include a plurality of sub-layers. For example, the lower layer DS' may include the buffer layer 101, the gate insulating layer 103, the first interlayer insulating layer 105, the second interlayer insulating layer 107, the first organic insulating layer 111, and the second organic insulating layer 112. However, the disclosure is not limited thereto. According to some embodiments, the lower layer DS' may further include other layers, or some of the above-described layers may be omitted.

The buffer layer 101, the gate insulating layer 103, the first interlayer insulating layer 105, the second interlayer insulating layer 107, and the first organic insulating layer 111 may each include an opening overlapping the second area AR2′. The second organic insulating layer 112 may cover the openings of the buffer layer 101, the gate insulating layer 103, the first interlayer insulating layer 105, the second interlayer insulating layer 107, and the first organic insulating layer 111. However, the disclosure is not limited thereto. According to some embodiments, the buffer layer 101, the gate insulating layer 103, the first interlayer insulating layer 105, the second interlayer insulating layer 107, and the first organic insulating layer 111 included in the lower layer DS' may all include an opening corresponding to the second area AR2′.

An upper surface of the lower layer DS′, for example, an upper surface of the second organic insulating layer 112, may include the first surface portion FP1, the second surface portion FP2, and the inclined surface portion SP. The first surface portion FP1 and the second surface portion FP2 may have a step therebetween. The first area AR1′ may include the step area ST provided at a boundary with the second area AR2′. The inclined surface portion SP may be arranged in the step area ST. The second edge E2 that is a boundary line between the inclined surface portion SP and the second surface portion FP2 may correspond to a boundary between the first area AR1′ and the second area AR2′.

The transparent conductive wiring TWL1 may be located on the lower layer DS′. As described above with reference to FIG. 15, the transparent conductive wiring TWL1 may be a wiring that electrically connects the second light-emitting diode ED2 of the second display area DA2 to the second sub-pixel circuit PC2 (see FIG. 15) arranged in the third display area DA3 (see FIG. 15). The transparent conductive wiring TWL1 may extend in the first direction (e.g., the x-direction) from the first area AR1′ toward the second area AR2′ through the step area ST. According to some embodiments, a plurality of transparent conductive wirings TWL1 may be provided, and the plurality of transparent conductive wirings TWL1 may be spaced apart from each other. The plurality of transparent conductive wirings TWL1 may be located on the inclined surface portion SP of the lower layer DS′.

According to some embodiments, the lower layer DS' of FIG. 16 may correspond to the lower layer DS of FIGS. 5 to 11. Also, the transparent conductive wiring TWL1 of FIG. 16 may correspond to the wiring L of FIGS. 5 to 11. Accordingly, in a plan view, the plurality of transparent conductive wirings TWL1 may include two adjacent transparent conductive wirings TWL1, and a portion in which one of the two adjacent transparent conductive wirings TWL1 overlaps the inclined surface portion SP of the lower layer DS' may be arranged in a diagonal direction crossing the first direction with respect to a portion in which the other one overlaps the inclined surface portion SP. Accordingly, instances of a short circuit occurring between the plurality of transparent conductive wirings TWL1 passing through the lower layer DS' of the second display area DA2 may be prevented or reduced.

Although a lower layer and wiring structure of the second display area DA2 has been described with respect to FIGS. 12 to 16, the disclosure is not limited thereto. For example, the structure described with reference to FIGS. 5 to 11 may be applied to a lower layer and wiring structure having a stepped structure between the display area DA and the peripheral area PA.

According to the one or more embodiments, it may be possible to implement a display apparatus in which a short circuit defect between adjacent wirings in a stepped structure may be prevented and reduced. However, the scope of embodiments according to the present disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate comprising a first area and a second area adjacent to each other;
a plurality of wirings on the substrate and extending in a first direction from the first area toward the second area; and
a lower layer between the substrate and the plurality of wirings and comprising an inclined surface portion,
wherein the plurality of wirings comprise two adjacent wirings, and
in a plan view, a first portion in which one of the two adjacent wirings overlaps the inclined surface portion is in a diagonal direction crossing the first direction with respect to a second portion in which the other of the two adjacent wirings overlaps the inclined surface portion.

2. The display apparatus of claim 1, wherein, in a plan view, the inclined surface portion comprises an uneven shape in which a protruding portion and a recessed portion are repeatedly arranged.

3. The display apparatus of claim 2, wherein the protruding portion protrudes in a direction toward the second area, and
the recessed portion is recessed in a direction toward the first area.

4. The display apparatus of claim 2, wherein one of the two adjacent wirings overlaps the protruding portion of the inclined surface portion, and
the other of the two adjacent wirings overlaps the recessed portion of the inclined surface portion.

5. The display apparatus of claim 2, wherein the protruding portion and the recessed portion each have a quadrangular shape.

6. The display apparatus of claim 2, wherein the protruding portion and the recessed portion each have a triangular shape, and
the two adjacent wirings pass through vertices of the triangular shape.

7. The display apparatus of claim 1, wherein, in a plan view, the inclined surface portion comprises an oblique shape that is inclined with respect to the first direction and a second direction perpendicular to the first direction.

8. The display apparatus of claim 1, wherein the plurality of wirings are on a same layer and comprise a same material.

9. The display apparatus of claim 1, wherein the lower layer comprises a plurality of sub-layers.

10. The display apparatus of claim 1, further comprising a light-emitting diode on the substrate,
wherein the light-emitting diode comprises:
a sub-pixel electrode;
an emission layer on the sub-pixel electrode; and
an opposite electrode on the emission layer.

11. A display apparatus comprising:
a substrate comprising a first area and a second area adjacent to each other;
a plurality of wirings on the substrate and extending in a first direction from the first area toward the second area; and
a lower layer between the substrate and the plurality of wirings,
wherein an upper surface of the lower layer comprises:
a first surface portion in the first area;
a second surface portion in the second area and having a vertical distance that is smaller than a vertical distance from the substrate to the first surface portion; and
an inclined surface portion between the first surface portion and the second surface portion,
wherein the plurality of wirings comprise two adjacent wirings, and
in a plan view, a first portion in which one of the two adjacent wirings overlaps the inclined surface portion is arranged in a diagonal direction crossing the first direction with respect to a second portion in which the other of the two adjacent wirings overlaps the inclined surface portion.

12. The display apparatus of claim 11, wherein the inclined surface portion has a vertical distance that is smaller than the vertical distance from the substrate to the first surface portion and greater than a vertical distance from the substrate to the second surface portion.

13. The display apparatus of claim 11, wherein, in a plan view, the inclined surface portion comprises an uneven shape in which a protruding portion and a recessed portion are repeatedly arranged.

14. The display apparatus of claim 13, wherein the protruding portion is a portion that protrudes in a direction toward the second area, and
the recessed portion is a portion that is recessed in a direction toward the first area.

15. The display apparatus of claim 13, wherein one of the two adjacent wirings overlaps the protruding portion of the inclined surface portion, and
the other of the two adjacent wirings overlaps the recessed portion of the inclined surface portion.

16. The display apparatus of claim 13, wherein the protruding portion and the recessed portion each have a quadrangular shape.

17. The display apparatus of claim 13, wherein the protruding portion and the recessed portion each have a triangular shape, and
the two adjacent wirings pass through vertices of the triangular shape.

18. The display apparatus of claim 11, wherein, in a plan view, the inclined surface portion comprises an oblique shape that is inclined with respect to the first direction and a second direction perpendicular to the first direction.

19. The display apparatus of claim 1, wherein the plurality of wirings are on a same layer and comprise a same material.

20. The display apparatus of claim 1, wherein the lower layer comprises a plurality of sub-layers.
